(19) United States
(12) Patent Application Publication
(10) Pub. No.: US 2025/0336836 A1
(43) Pub. Date: Oct. 30, 2025

(54) SEMICONDUCTOR PACKAGE HAVING AUXILIARY SUBSTRATE

(71) Applicant: Micron Technology, Inc., Boise, ID (US)

(72) Inventors: Wang Lai LEE, Singapore (SG); Roslan Bin SAID, Singapore (SG)

(21) Appl. No.: 19/065,380

(22) Filed: Feb. 27, 2025

Related U.S. Application Data
(60) Provisional application No. 63/640,179, filed on Apr. 29, 2024.

(51) Int. Cl. H01L 23/538; H01L 21/48; H01L 23/00; H01L 23/498; H01L 25/065; H01L 25/18; H05K 1/14; H05K 1/18; H10B 80/00; H10D 80/30

(52) U.S. Cl. CPC H01L 23/5385; H01L 21/4853; H01L 23/49811; H01L 23/5383; H01L 24/32; H01L 24/48; H01L 24/91; H01L 25/0657; H01L 25/18; H05K 1/145; H05K 1/181; H10B 80/00; H10D 80/30; H01L 24/16; H01L 24/73; H01L 2224/16238; H01L 2224/32145; H01L 2224/32225; H01L 2224/48227; H01L 2224/73253; H01L 2224/73265; H01L 2224/91; H01L 2225/0651; H01L 2225/06562; H01L 2924/1431; H01L 2924/1436; H01L 2924/1438; H05K 2201/042; H05K 2201/10159; H05K 2201/10287

(57) ABSTRACT

Implementations described herein relate to various semiconductor device assemblies. In some implementations, a semiconductor device assembly includes a first substrate having first electrical traces and a second substrate having second electrical traces, where the second electrical traces are electrically coupled with the first electrical traces using at least one wire bond. The semiconductor device assembly includes an integrated circuit between the first substrate and the second substrate, where the integrated circuit is electrically coupled with the first electrical traces using at least one conductive structure.

### CROSS-REFERENCE TO RELATED APPLICATION

This Patent application claims priority to U.S. Provisional Patent Application No. 63/640,179, filed on Apr. 29, 2024, entitled “SEMICONDUCTOR PACKAGE HAVING AUXILIARY SUBSTRATE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a semiconductor package having an auxiliary substrate.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example implementation described herein.

FIG. 4 is a diagram of an example implementation described herein.

FIG. 5 is a flowchart of an example method of forming an integrated assembly or memory device having an auxiliary substrate.

FIG. 6 is a flowchart of an example method associated with a semiconductor package having an auxiliary substrate.

FIG. 7A through FIG. 7G are diagrammatic views showing formation of an integrated assembly or memory device having an auxiliary substrate described at stages of an example process described herein.

### DETAILED DESCRIPTION

A semiconductor package with a multi-layer substrate serves as the structural foundation for integrated circuits, offering both electrical connectivity and physical support. This package typically comprises several layers of insulating material, such as silicon dioxide or epoxy resin, interleaved with conductive traces made of copper or aluminum. These layers are intricately stacked to form a compact yet robust structure.

One of the key advantages of utilizing a multi-layer substrate is the optimization of signal routing. By incorporating multiple layers, designers can minimize trace lengths, reducing signal parasitic degradation and improving overall circuit performance. This design approach is particularly crucial in high-speed applications, such as microprocessors and communication devices, where even slight delays can impact functionality.

However, in some cases, the incorporation of multiple layers inevitably leads to an increase in package thickness. As each layer adds to the overall height of the substrate, the thickness of the package escalates accordingly. This increase in thickness can pose challenges, especially in applications where space constraints are critical. Engineers must carefully balance the benefits of shorter trace lengths with the trade-off of increased package thickness to ensure that the final semiconductor package meets the requirements of the intended application.

Some implementations described herein include a semiconductor package including an auxiliary substrate. The auxiliary substrate may be located over and/or on a semiconductor die and connect with traces of a primary substrate and/or another semiconductor die included in the semiconductor package. Use of the auxiliary substrate may enable shortened trace lengths within the semiconductor package while simultaneously enabling the primary substrate to have a reduced layer count.

In this way, a performance of integrated circuitry included in the semiconductor package (e.g., integrated circuitry included on the semiconductor dies) may be maintained and/or improved to satisfy a performance threshold (e.g., a quality and/or a reliability threshold related to parasitic degradation of a signal). Additionally, a thickness of the semiconductor package may be maintained and/or improved to satisfy a space constraint threshold. In this way, an amount of resources used to support a market consuming the semiconductor package (e.g., labor, raw materials, semiconductor manufacturing tools, and/or computing resources) is reduced.

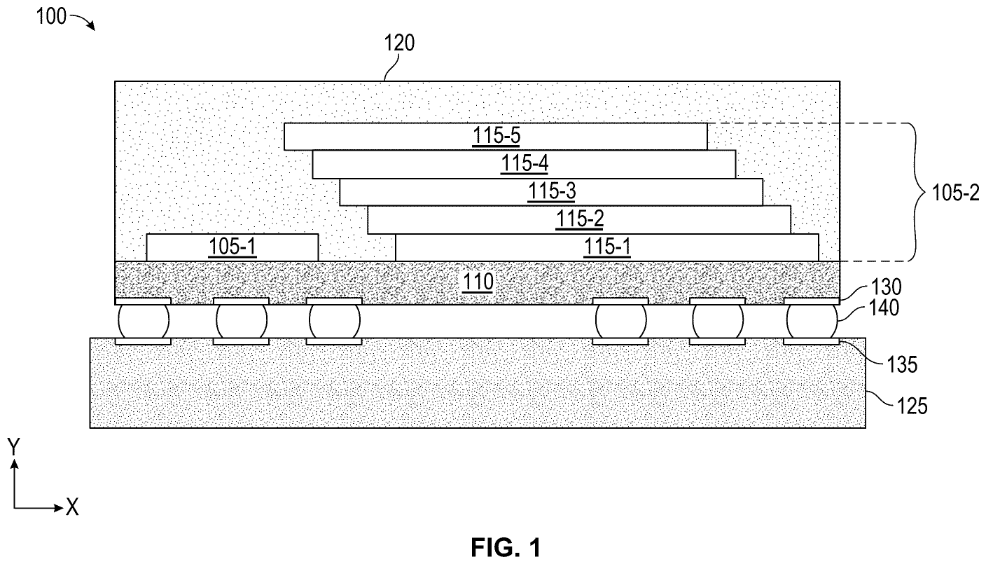

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a shingle stack (e.g., with die edges that are not aligned, which provides space for wire bonding near the edges of the dies 115), in some implementations, the dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

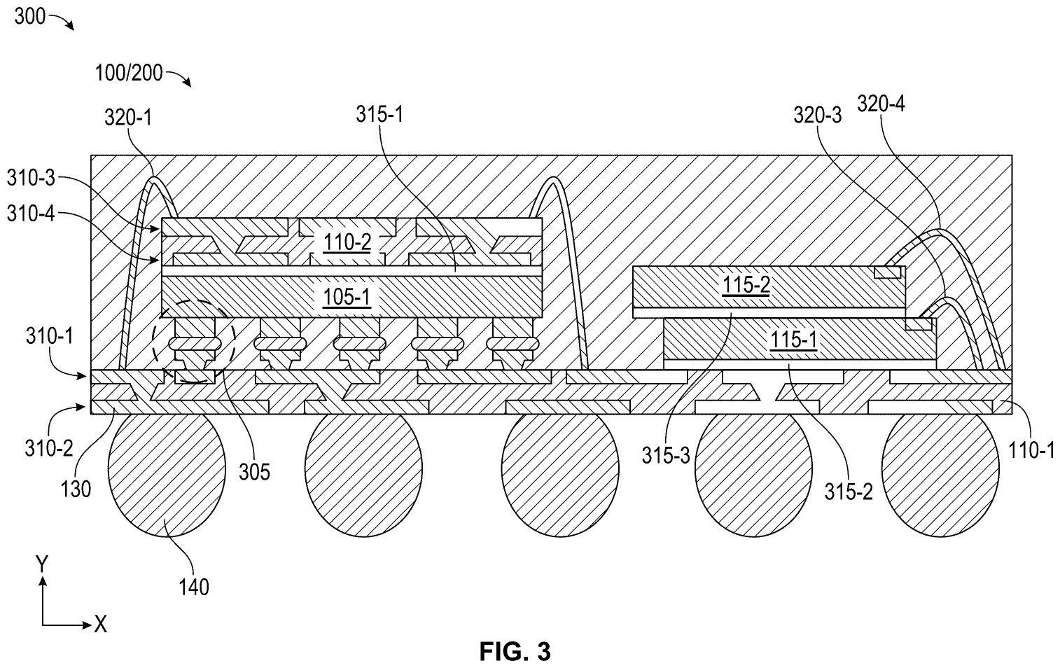

As described in greater detail in connection with FIG. 3 through FIG. 7G, the apparatus 100 may include an additional substrate (e.g., a second, or auxiliary, substrate) that is over and/or on the integrated circuit 105 and/or the dies 115. The additional substrate may enable a layer count (e.g., a quantity of conductive layers) within the substrate 110 to be maintained and/or reduced such that an overall thickness of the apparatus 100 satisfies a space constraint threshold. Additionally, or alternatively, lengths of traces and/or electrical connections among the dies 115 and/or the solder balls 140 may be maintained to satisfy a performance threshold (e.g., a parasitic degradation threshold) to maintain and/or increase a manufacturing yield of the apparatus 100.

As indicated above, FIG. 1 is provided as an example. Other examples may differ from what is described with regard to FIG. 1.

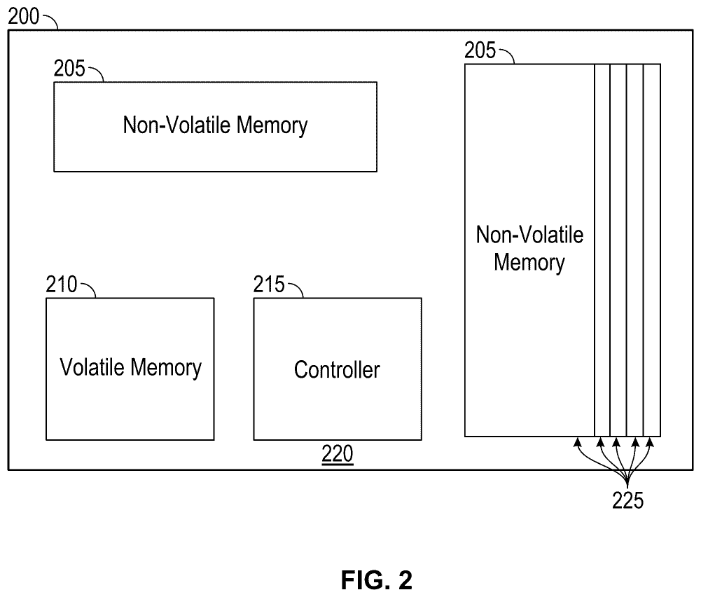

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

In some implementations, the memory device 200 includes one or more features described in connection with FIG. 1. Additionally, or alternatively, and as described in greater detail in connection with FIG. 3 through FIG. 7G, the memory device 200 may include an additional substrate (e.g., a second, or auxiliary, substrate) that is over and/or on the non-volatile memory 205, the volatile memory 210, and/or the controller 215. The additional substrate may enable a layer count (e.g., a quantity of conductive layers) within the substrate 220 to be maintained and/or reduced such that an overall thickness of the memory device 200 satisfies a space constraint threshold. Additionally, or alternatively, lengths of traces and/or electrical connections among the non-volatile memory 205, the volatile memory 210, and/or the controller 215 may be maintained to satisfy a performance threshold (e.g., a parasitic degradation threshold) to maintain and/or increase a manufacturing yield of the memory device 200.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIG. 3 is a diagram of an example implementation 300 described herein. The implementation 300 may correspond to a portion of the apparatus 100 of FIG. 1 and/or a portion of the memory device 200 of FIG. 2. Additionally, or alternatively, the implementation 300 may correspond to a semiconductor package including one or more dies 115 (e.g., the integrated circuit 105-1, the die 115-1, and the die 115-2).

As shown in FIG. 3, the integrated circuit 105-1 is on the substrate 110-1. The substrate 110-1 includes a conductive layer 310-1 and a conductive layer 310-2. The conductive layers 310-1 and 310-2 (e.g., metallization layers or traces) may include a conductive material such as aluminum, copper, tungsten, gold, silver, nickel, or another suitable conductive material, among other examples. The metallization layers 310-1 and 310-2 may be electrically isolated and separated by insulative layers (e.g., dielectric layers).

In some implementations, the substrate 110-1 corresponds to a multi-layer printed circuit board (PCB), a package substrate, or an organic interposer.

Alternatively, and in some implementations, the substrate 110-1 corresponds to a silicon substrate, a ceramic substrate, or a glass substrate where the conductive layers 310-1 and 310-2 are redistribution layers (RDLs).

In some implementation, the integrated circuit 105-1 includes a front side and back side. The front side of the integrated circuit 105-1 couples to the substrate 110-1. In some implementations, the integrated circuit 105-1 is a flip chip semiconductor die that electrically couples to the substrate 110-1 using conductive structures 305 (e.g., conductive structures including pillars and/or solder bumps). The conductive structures 305 may include a combination of one or more conductive materials such as aluminum, copper, tungsten, gold, silver, nickel, or other suitable conductive materials, among other examples. In some implementations, integrated circuit 105-1 can be connected to the substrate 110-1 in multiple ways (solder balls, pillars, u-pillars, and/or copper interconnects). Additionally, and in some implementations, the integrated circuit 105-1 includes integrated circuitry (e.g., controller integrated circuitry, logic integrated circuitry).

As further shown in FIG. 3, the substrate 110-2 (e.g., a second or auxiliary substrate) is over and/or on the integrated circuit 105. In some implementations, the substrate 110-2 may be fixed to the integrated circuit 105-1 using an adhesive film 315-1 (e.g., a tape or a die attach film (DAF)), where the adhesive film 315-1 is between the substrate 110-2 and the integrated circuit 105-1. In some other implementations, the substrate 110-2 may be bonded to the integrated circuit 105-1.

The substrate 110-2 includes one or more conductive layers. In the implementation of FIG. 3, the substrate 110-2 includes a conductive layer 310-3 and a conductive layer 310-4. The conductive layers 310-3 and 310-4 (e.g., metallization layers or traces) may include a conductive material such as aluminum, copper, tungsten, gold, silver, nickel, or another suitable conductive material, among other examples. The metallization layers 310-3 and 310-4 may be electrically isolated and separated by insulative layers (e.g., dielectric layers).

In some implementations, the substrate 110-2 corresponds to a multi-layer printed circuit board (PCB), package substrate or an organic interposer. Alternatively, and in some implementations, the substrate 110-2 corresponds to a silicon substrate, a ceramic substrate, or a glass substrate where the conductive layers 310-3 and 310-4 are redistribution layers (RDLs).

Although FIG. 3 shows the substrate 110-1 including a quantity of two conductive layers (e.g., the conductive layers 310-1 and 310-2) and the substrate 110-2 including a quantity of two conductive layers (e.g., the conductive layers 310-3 and 310-4), some implementations may include different quantities of layers. For example, the substrate 110-1 may include a quantity of three conductive layers and the substrate 110-2 may include a quantity of two conductive layers, the substrate 110-1 may include a quantity of four conductive layers and the substrate 110-2 may include a quantity of three conductive layers, and so on.

In some implementations, the quantity of conductive layers included in the substrate 110-2 is less than or equal to the quantity of conductive layers included in the substrate 110-1. Furthermore, the quantities of conductive layers included in the substrate 110-1 and the substrate 110-2 may be determined based on a targeted thickness threshold (e.g., a thickness of the apparatus 100 or the memory device 200) and/or a targeted trace length threshold.

As shown in FIG. 3, the substrate 110-2 is directly over the substrate 110-1. In other words, the substrate 110-2 may not have ends and/or edges that overlap and extend beyond a perimeter of the substrate 110-1.

In some implementations, a footprint and/or an area of the substrate 110-2 may be less than or equal to a footprint and/or an area of the integrated circuit 105-1 (e.g., the substrate 110-2 may not have ends and/or edges that overlap and extend beyond a perimeter of the integrated circuit 105-1). Alternatively, and in some implementations, a footprint and/or an area of the substrate 110-2 may be greater than a footprint and/or an area of the integrated circuit 105-1 (e.g., the substrate 110-2 may have ends and/or edges that overlap and extend beyond a perimeter of the integrated circuit 105-1).

As shown in FIG. 3, the conductive layer 310-3 is electrically coupled with the conductive layer 310-1 using wire bonds 320-1 and 320-2. The wire bond 320-1 and/or 320-2 may include a conductive material such as aluminum, copper, gold, or another suitable conductive material, among other examples. In some implementations, a trace of the conductive layer 310-1 may be electrically coupled to the solder ball 140 through the conductive layer 310-1 and/or the conductive layer 310-2.

In some implementations, the substrate 110-2 on the integrated circuit 105 is referred to as a “substrate on die” configuration. However, and in some implementations, a spacer that is devoid of integrated circuitry (e.g., a blank silicon die, a blank ceramic die) may be substituted for the integrated circuit 105-1 having the integrated circuitry. In such an implementation, the substrate 110-2 on the spacer may be referred to as a “substrate on spacer” configuration.

As shown in FIG. 3, the die 115-1 is over and/or on the substrate 110-1. The die 115-1 may be fixed to the substrate 110-2 using the adhesive film 315-2, where the adhesive film 315-2 is between the die 115-1 and the substrate 110-1. The die 115-1 may electrically couple with the conductive layer 310-1 using the wire bond 320-3, thereby enabling the die 115-1 to electrically couple with the integrated circuit 105-1 and/or the solder ball 140 through the substrate 110-2.

Furthermore, the die 115-2 is over and/or on the die 115-1. The die 115-2 may be fixed to the die 115-1 using the adhesive film 315-3, where the adhesive film 315-3 is between the die 115-2 and the die 115-1. The die 115-2 may electrically couple with the conductive layer 310-1 using the wire bond 320-4, thereby enabling the die 115-2 to electrically couple with the integrated circuit 105-1 and/or the solder ball 140 through the substrate 110-2.

In some implementations, the die 115-1 and/or the die 115-2 include memory integrated circuitry. The memory integrated circuitry may be dynamic random access memory integrated circuitry (DRAM integrated circuitry) or NAND memory integrated circuitry, among other examples.

As shown in FIG. 3, and in some implementations, the casing 120 encapsulates the integrated circuit 105-1, the die 115-1, and the die 115-2 on the substrate 110-1. Additionally, and in some implementations, the casing 120 encapsulates the substrate 110-2, the wire bond 320-1, the wire bond 320-2, the wire bond 320-3, and the wire bond 320-4 on the substrate 110-1.

As indicated above, FIG. 3 is provided as an example. Other examples may differ from what is described with regard to FIG. 3.

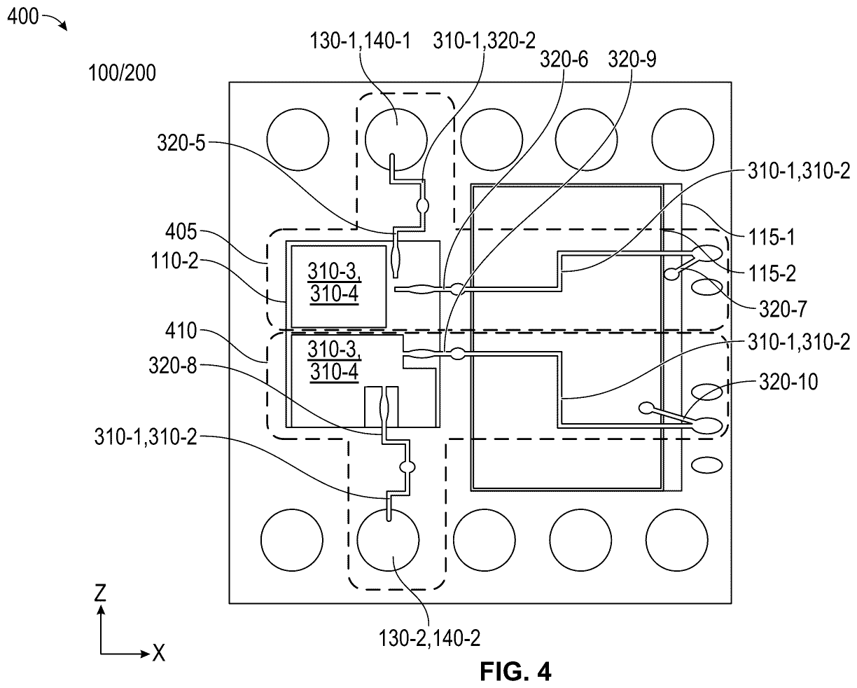

FIG. 4 is a diagram of an example implementation 400 described herein. FIG. 4 shows an example footprint (e.g., from a top view perspective) of a portion of the apparatus 100 of FIG. 1 and/or a portion of the memory device 200 of FIG. 2. Additionally, or alternatively, the footprint may correspond to a footprint of a semiconductor package including one or more dies 115 (e.g., the integrated circuit 105-1, the die 115-1, and the die 115-2).

As shown in FIG. 4, a circuit 405 may include portions of the conductive layers 310-3 and 310-4. The circuit 405 may further include portions of the conductive layers 310-1 and 310-2, multiple wire bonds (e.g., the wire bond 320-5, the wire bond 320-6, and the wire bond 320-7), and or the electrical contact 130-1. In some implementations, the circuit 405 electrically couples the die 115-1 to solder ball 140-1 (or another external interconnect structure) through the substrate 110-2. In some implementations, the circuit 405 (e.g., an electrical connection) is part of a voltage supply circuit for powering a memory cell.

As further shown in FIG. 4, a circuit 410 may include portions of the conductive layers 310-3 and 310-4. The circuit 405 may further include portions of the conductive layers 310-1 and 310-2 and multiple wire bonds (e.g., the wire bond 320-8, the wire bond 320-9, and the wire bond 320-10). In some implementations, the circuit 410 electrically couples the die 115-5 to the electrical contact 130-2 and/or the solder ball 140-2 (or another external interconnect structure) through the substrate 110-2. In some implementations, the circuit 410 (e.g., an electrical connection) is part of a voltage supply circuit for powering input integrated circuitry and/or output integrated circuitry.

As indicated above, FIG. 4 is provided as an example. Other examples may differ from what is described with regard to FIG. 4.

As described in connection with FIGS. 1-4, and in some implementations, a semiconductor device assembly (e.g., the apparatus 100, the memory device 200) includes a first substrate (e.g., the substrate 110-1) having first electrical traces (e.g., the conductive layer 310-1) and a second substrate (e.g., the substrate 110-2) having second electrical traces (e.g., the conductive layer 310-3). In some implementations, the second electrical traces are electrically coupled with the first electrical traces using at least one wire bond (e.g., the wire bond 320-1). The semiconductor device assembly includes an integrated circuit (e.g., the integrated circuit 105-1) between the first substrate and the second substrate. In some implementations, the integrated circuit is electrically coupled with the first electrical traces using at least one conductive structure (e.g., the conductive structures 305).

Additionally, or alternatively and in some implementations, an apparatus (e.g., the apparatus 100, the memory device 200) includes a first substrate (e.g., the substrate 110-1) having a first quantity of two or more first conductive layers (e.g., the conductive layers 310-1 and 310-2). The apparatus includes a second substrate (e.g., the substrate 110-2) directly over the first substrate having a second quantity of two or more second conductive layers (e.g., the conductive layers 310-3 and 310-4). In some implementations, the second quantity is less than or equal to the first quantity. The apparatus further includes a semiconductor die (e.g., the integrated circuit 105-1) that is between the first substrate and the second substrate and that includes including controller integrated circuitry. The apparatus further includes a stack of two or more semiconductor dies (e.g., the dies 115-1 and 115-2) that is laterally adjacent to the second substrate. Each of the semiconductor dies includes memory integrated circuitry, where the memory integrated circuitry is electrically coupled with the controller integrated circuitry through at least one of the two or more first conductive layers and at least one of the two or more second conductive layers.

Additionally, or alternatively, and in some implementations, a semiconductor package (e.g., the apparatus 100) includes a first substrate (e.g., the substrate 110-1) that includes a pad structure (e.g., the pad structure). The semiconductor package includes an external interconnect structure (e.g., the solder ball 140) on the pad structure. The semiconductor package includes a second substrate (e.g., the substrate 110-2) that includes a metallization layer (e.g., the conductive layer 310-3). The semiconductor package includes a spacer (e.g., the integrated circuit 105-1) that is between the first substrate and the second substrate. The semiconductor package includes a semiconductor die (e.g., the die 115-1) on the first substrate, where an electrical connection between the semiconductor die and the external interconnect structure includes the metallization layer and the pad structure.

In this way, trace lengths are reduced, to maintain and/or improve a performance of integrated circuitry and satisfy a performance threshold (e.g., a quality and/or a reliability threshold related to parasitic degradation of a signal). Additionally, a thickness of the semiconductor device assembly, apparatus, or semiconductor package may be maintained and/or improved to satisfy a space constraint threshold. In this way, an amount of resources used to support a market consuming the semiconductor device assembly, apparatus, or semiconductor package (e.g., labor, raw materials, semiconductor manufacturing tools, and/or computing resources) is reduced.

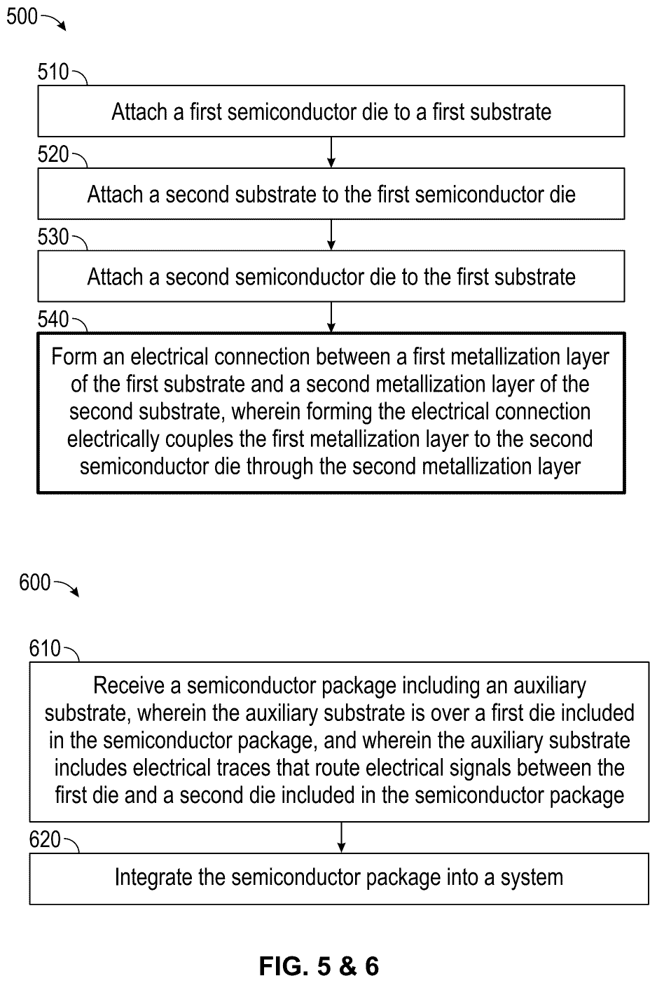

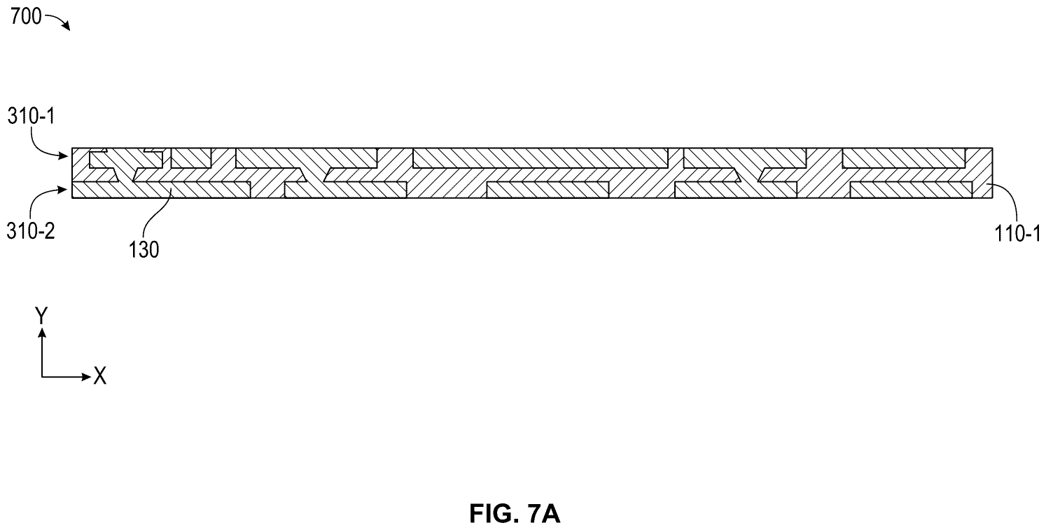

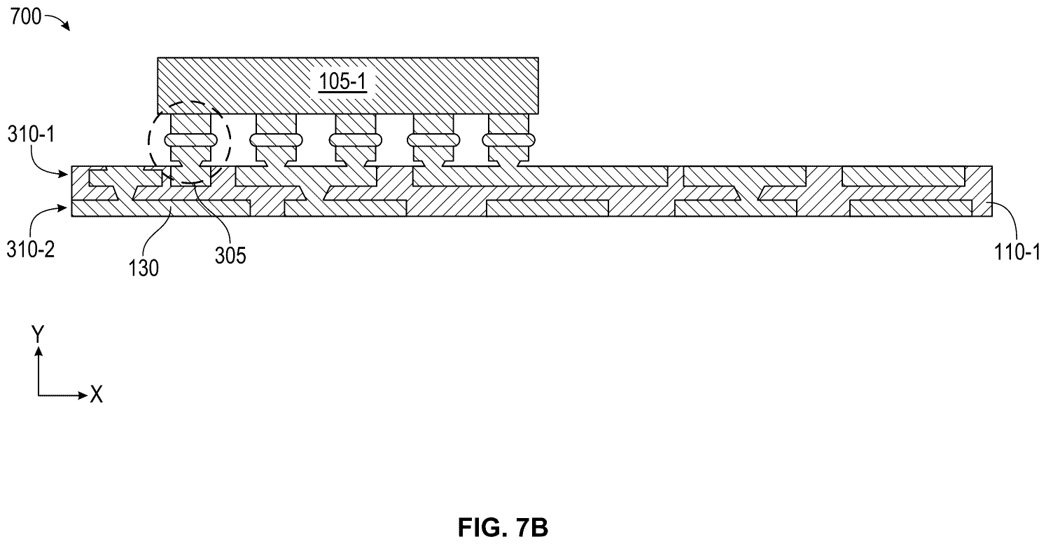

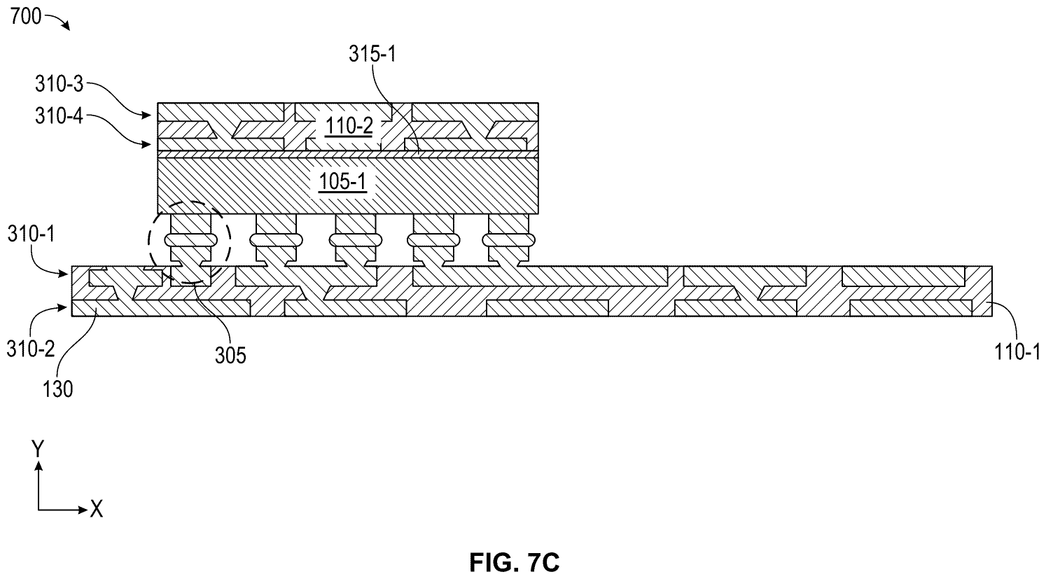

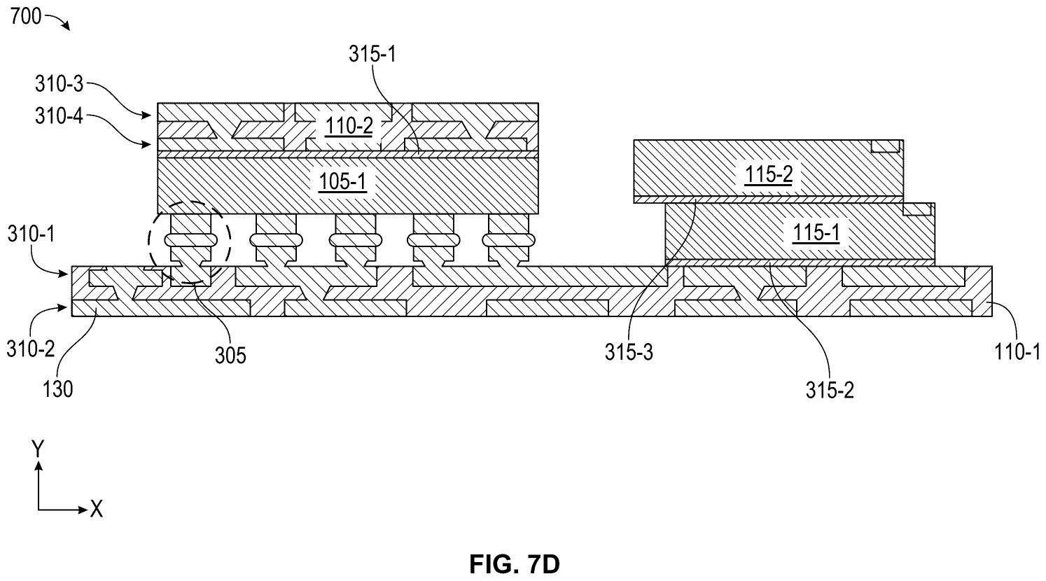

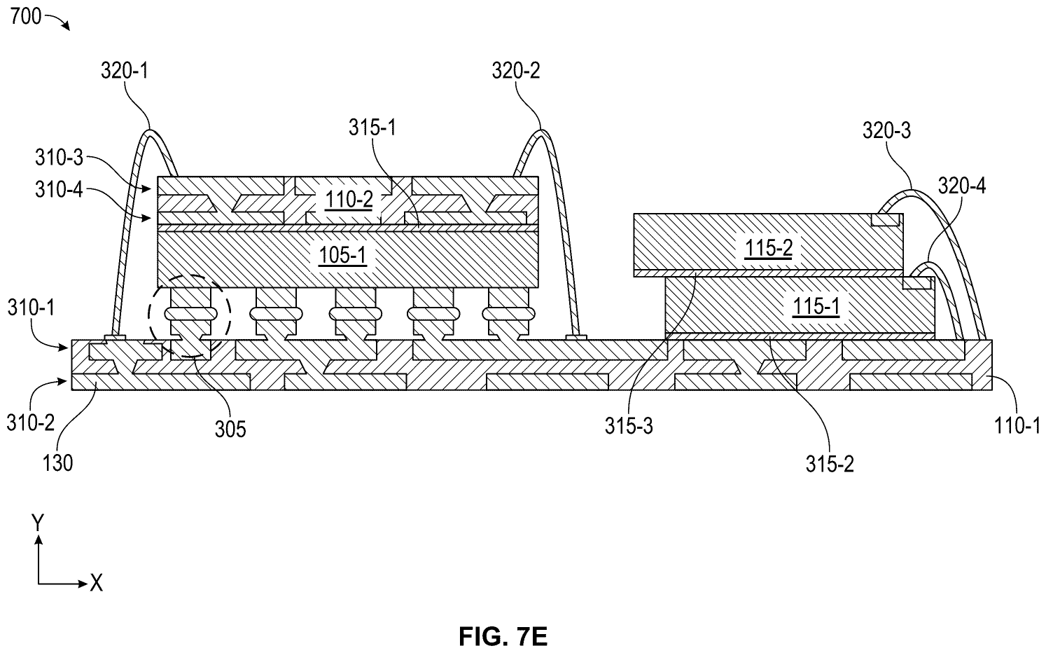

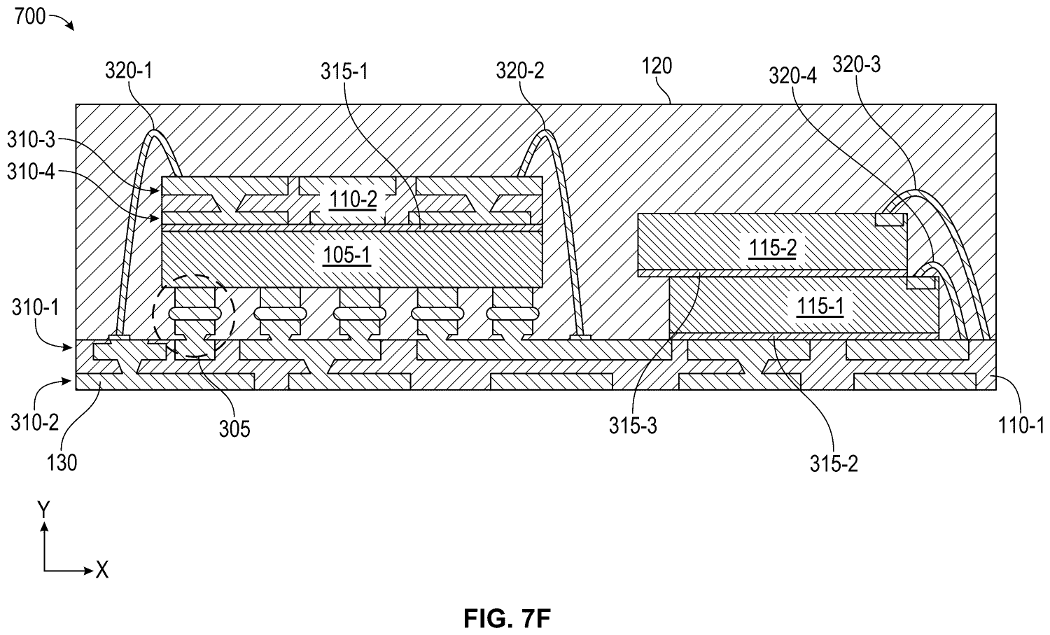

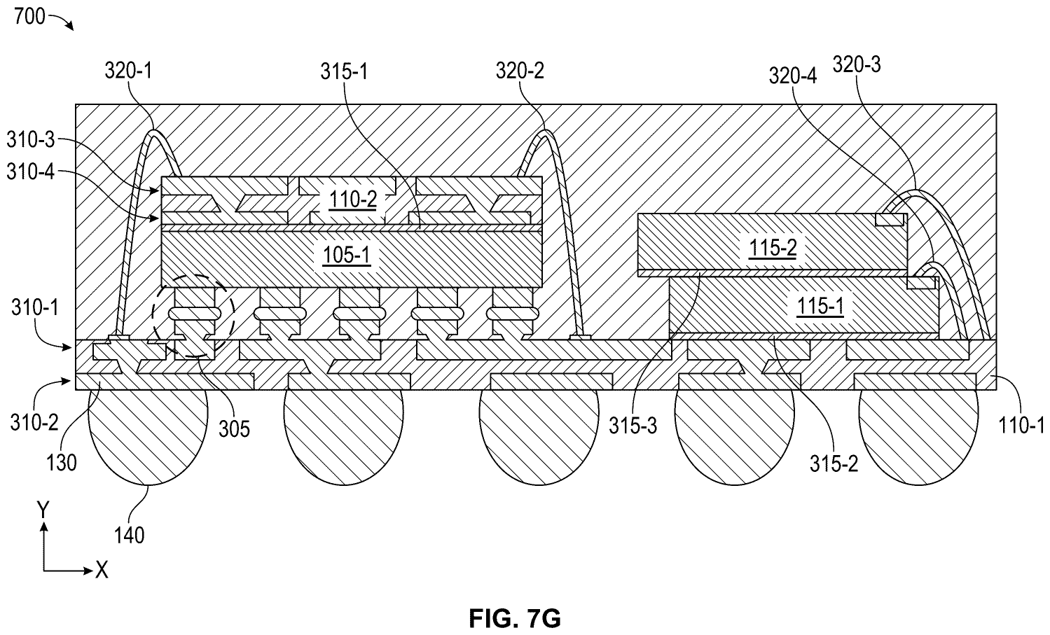

FIG. 5 is a flowchart of an example method 500 of forming an integrated assembly (e.g., the apparatus 100) or memory device (e.g., the memory device 200) having an auxiliary substrate (e.g., the substrate 110-2). In some implementations, and as described in greater detail in connection with FIG. 7A through FIG. 7G, one or more process blocks of FIG. 5 may be performed by various semiconductor manufacturing equipment.

As shown in FIG. 5, the method 500 may include attaching a first semiconductor die (e.g., the integrated circuitry 105-1) to a first substrate (e.g., the substrate 110-1) (block 510). As further shown in FIG. 5, the method 500 may include attaching a second substrate (e.g., the substrate 110-2) to the first semiconductor die (block 520). As further shown in FIG. 5, the method 500 may include attaching a second semiconductor die (e.g., the die 115-1) to the first substrate (block 530). As further shown in FIG. 5, the method 500 may include forming an electrical connection (e.g., the wire bond 320-1) between a first metallization layer (e.g., the conductive layer 310-1) of the first substrate and a second metallization layer (e.g., the conductive layer 310-3) of the second substrate. In some implementations, forming the electrical connection electrically couples the first metallization layer to the second semiconductor die through the second metallization layer (block 540).

The method 500 may include additional aspects, such as any single aspect or any combination of aspects described below and/or in connection with one or more other methods described elsewhere herein.

In a first aspect, attaching the second substrate to the first semiconductor die includes attaching the second substrate to the first semiconductor die using an adhesive film (e.g., the adhesive film 315-1).

In a second aspect, alone or in combination with the first aspect, attaching the second semiconductor die to the first substrate electrically couples the second semiconductor die to the first metallization layer.

In a third aspect, alone or in combination with one or more of the first and second aspects, forming the electrical connection includes forming a wire bond connection (e.g., the wire bond 320-1).

In a fourth aspect, alone or in combination with one or more of the first through third aspects, the electrical connection is a first electrical connection and the method 500 includes forming a second electrical connection (e.g., the wire bond 320-3) between the second semiconductor die and a metallization layer of the first substrate.

In a fifth aspect, alone or in combination with one or more of the first through fourth aspects, forming the second electrical connection includes forming a wire bond connection (e.g., the wire bond 320-3).

In a sixth aspect, alone or in combination with one or more of the first through fifth aspects, the method 500 includes forming, over the first substrate, a casing (e.g., the casing 120) that encapsulates the first semiconductor die, the second substrate, the second semiconductor die, and the electrical connection.

Although FIG. 5 shows example blocks of the method 500, in some implementations, the method 500 may include additional blocks, fewer blocks, different blocks, or differently arranged blocks than those depicted in FIG. 5.

FIG. 6 is a flowchart of an example method 600 associated with a semiconductor package (e.g., the apparatus 100 or the memory device 200) having an auxiliary substrate (e.g., the substrate 110-2). In some implementations, the method may be performed at an original equipment manufacturer (OEM) or an outsourced assembly and test (OSAT) manufacturer using a combination of semiconductor manufacturing equipment.

As shown in FIG. 6, the method 600 may include receiving a semiconductor package including an auxiliary substrate. In some implementations, the auxiliary substrate is over a first die (e.g., the integrated circuit 105-1) included in the semiconductor package. In some implementations, the auxiliary substrate includes electrical traces (e.g., the conductive layers 310-3 and/or the conductive layers 310-4) that route electrical signals between the first die and a second die (e.g., the die 115-1) included in the semiconductor package (block 610). As further shown in FIG. 6, the method 600 may include integrating the semiconductor package into a computing system (block 620).

The method 600 may include additional aspects, such as any single aspect or any combination of aspects described below and/or described in connection with one or more other methods or operations described elsewhere herein.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel.

FIG. 7A through FIG. 7G are diagrammatic views showing formation of an integrated assembly (e.g., the apparatus 100) or memory device (e.g., the memory device 200) having an auxiliary substrate (e.g., the substrate 110-2) described at stages of an example process 700 described herein. In some implementations, the process 700 described below in connection with FIG. 7A through FIG. 7G may correspond to the method 500, one or more blocks of the method 500, the method 600, and/or one or more blocks of the method 600. However, the process described below is an example, and other example processes may be used to form the stress reduction structure, an integrated assembly that includes the stress reduction structure, and/or one or more parts of an integrated assembly including the stress reduction structure.

As shown in FIG. 7A, the process 700 may include receiving the substrate 110-1. Receiving the substrate 110-1 may include receiving the substrate 110-1 from a supplier such as a multi-layer PCB supplier. Alternatively, receiving the substrate 110-1 may include receiving the substrate 110-1 from a foundry that fabricates silicon or ceramic substrates having redistribution layers, among other examples. As shown in FIG. 7A, the substrate 110-1 includes the conductive layer 310-1 that is electrically coupled with the conductive layer 310-2. The conductive layer 310-2 may include the electrical contact 130.

As shown in FIG. 7B, the process 700 may include attaching the integrated circuit 105-1 to the substrate 110-1. Attaching the integrated circuit 105-1 to the substrate 110-1 may include, for example, using a surface mount (SMT) process. The SMT process may use pick and place tools, solder dispense/screening tools, and reflow tools that attach the integrated circuit 105-1 to the substrate 110-1 using the conductive structures 305. The conductive structures 305 may electrically couple the integrated circuit 105-1 to the conductive layer 310-1. Alternatively, attaching the integrated circuit 105-1 to the substrate may include using a die attach process that uses an adhesive film to attach the integrated circuit 105-1 to the substrate 110-1.

As shown in FIG. 7C, the process 700 may include receiving the substrate 110-2. Receiving the substrate 110-2 may include receiving the substrate 110-2 from a supplier such as a multi-layer PCB supplier. Alternatively, receiving the substrate 110-2 may include receiving the substrate 110-2 from a foundry that fabricates silicon or ceramic substrates having redistribution layers, among other examples. As shown in FIG. 7C, the substrate 110-2 includes the conductive layer 310-3 that is electrically coupled with the conductive layer 310-4.

As further shown in FIG. 7C, the process 700 may include attaching the substrate 110-2 to the integrated circuit 105-1. Attaching the substrate 110-2 to the integrated circuit 105-1 may include using a die attach process. The die attach process may use a pick and place tool that attaches the substrate 110-2 to the integrated circuit 105-1 using the conductive film 315-1, among other examples.

As shown in FIG. 7D, the process 700 may include attaching the die 115-1 to the substrate 110-1. Attaching the die 115-1 to the substrate 110-1 may include using a die attach process. The die attach process may use a pick and place tool that attaches the die 115-1 to the substrate 110-1 using the conductive film 315-2, among other examples.

As further shown in FIG. 7D, the process 700 may include attaching the die 115-2 to the die 115-1. Attaching the die 115-2 to the die 115-1 may include using a die attach process. The die attach process may use a pick and place tool that attaches the die 115-2 to the die 115-2 using the conductive film 315-3, among other examples.

As shown in FIG. 7E, the process 700 may include forming the wire bonds 320-1 through 320-4. Forming the wire bonds 320-1 through 320-4 may include a wire bonding tool performing a wire bonding operation to form the wire bonds 320-1 through 320-4. Forming the wire bonds 320-1 through 320-4 may form a combination of electrical connections among the integrated circuit 105-1, the die 115-1, the die 115-2, and the substrate 110-1, where the electrical connections route through the substrate 110-2.

As shown in FIG. 7F, the process 700 may include forming the casing 120. Forming the casing may include using an encapsulation process. The encapsulation process may use a molding tool such as an injection molding tool, a compression molding tool, or a transfer molding tool that forms the casing 120. The casing 120 may encapsulate (e.g., surround) the integrated circuit 105-1, the substrate 110-2, the die 115-1, the die 115-2, the wire bonds 320-1 through 320-4, and the conductive structures 305 on the substrate 110-1.

As shown in FIG. 7G, the process 700 may include forming the solder balls 140. Forming the solder balls 140 may include a solder ball attach process. The solder ball attach process may include using a solder ball placement tool, a stencil printing tool, or a solder ball dispensing tool to form solder structures on the electrical contacts 130. The solder ball attach process may further include using a reflow tool that heats the solder structures to reflow the solder structures and form the solder balls 140.

As indicated above, the process 700 described in connection with FIG. 7A through FIG. 7G is provided as an example. Other examples may differ from what is described with respect to FIG. 7A through FIG. 7G.

In some implementations, a semiconductor device assembly includes a first substrate, comprising: first electrical traces; a second substrate, comprising: second electrical traces, wherein the second electrical traces are electrically coupled with the first electrical traces using at least one wire bond; and an integrated circuit between the first substrate and the second substrate, wherein the integrated circuit is electrically coupled with the first electrical traces using at least one conductive structure.

In some implementations, a semiconductor device assembly includes a first substrate, comprising: first electrical traces; a second substrate, comprising: second electrical traces; a first integrated circuit between the first substrate and the second substrate; and a second integrated circuit on the first substrate, wherein the second integrated circuit is electrically coupled with the first integrated circuit through the first electrical traces and the second electrical traces.

In some implementations, an apparatus includes a first substrate, comprising: a first quantity of two or more first conductive layers; a second substrate directly over the first substrate, comprising: a second quantity of two or more second conductive layers, wherein the second quantity is less than or equal to the first quantity; a semiconductor die between the first substrate and the second substrate, comprising: controller integrated circuitry; and a stack of two or more semiconductor dies laterally adjacent to the second substrate, comprising: memory integrated circuitry, wherein the memory integrated circuitry is electrically coupled with the controller integrated circuitry through at least one of the two or more first conductive layers and at least one of the two or more second conductive layers.

In some implementations, a semiconductor package includes a first substrate, comprising; a pad structure; an external interconnect structure on the pad structure; a second substrate, comprising: a metallization layer; a spacer that is between the first substrate and the second substrate; and a semiconductor die on the first substrate, wherein an electrical connection between the semiconductor die and the external interconnect structure includes the metallization layer and the pad structure.

In some implementations, a method includes attaching a first semiconductor die to a first substrate; attaching a second substrate to the first semiconductor die; attaching a second semiconductor die to the first substrate; and forming an electrical connection between a first metallization layer of the first substrate and a second metallization layer of the second substrate, wherein forming the electrical connection electrically couples the first metallization layer to the second semiconductor die through the second metallization layer.

In some implementations, a method includes receiving a semiconductor package including an auxiliary substrate, wherein the auxiliary substrate is over a first die included in the semiconductor package, and wherein the auxiliary substrate includes electrical traces that route electrical signals between the first die and a second die included in the semiconductor package; and integrating the semiconductor package into a system.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a first substrate, comprising:
first electrical traces;
a second substrate, comprising:
second electrical traces,
wherein the second electrical traces are electrically coupled with the first electrical traces using at least one wire bond; and
an integrated circuit between the first substrate and the second substrate,
wherein the integrated circuit is electrically coupled with the first electrical traces using at least one conductive structure.

2. The semiconductor device assembly of claim 1, wherein the integrated circuit is a first integrated circuit and further comprising:
a second integrated circuit on the first substrate,
wherein the second integrated circuit is electrically coupled with the first integrated circuit through the first electrical traces and the second electrical traces.

3. The semiconductor device assembly of claim 1, further comprising:
a wire bond that electrically couples the second electrical traces and the first electrical traces.

4. The semiconductor device assembly of claim 1, further comprising:
an adhesive film between the second substrate and the integrated circuit.

5. The semiconductor device assembly of claim 1, wherein the second substrate comprises:
a multi-layer printed circuit board.

6. The semiconductor device assembly of claim 5, wherein the second electrical traces comprise:
a first metallization layer of the multi-layer printed circuit board, and
a second metallization layer of the multi-layer printed circuit board.

7. An apparatus, comprising:
a first substrate, comprising:
a first quantity of two or more first conductive layers;
a second substrate directly over the first substrate, comprising:
a second quantity of two or more second conductive layers,
wherein the second quantity is less than or equal to the first quantity;
a semiconductor die between the first substrate and the second substrate, comprising:
controller integrated circuitry; and
a stack of two or more semiconductor dies laterally adjacent to the second substrate, comprising:
memory integrated circuitry,
wherein the memory integrated circuitry is electrically coupled with the controller integrated circuitry through at least one of the two or more first conductive layers and at least one of the two or more second conductive layers.

8. The apparatus of claim 7, wherein the semiconductor die including the controller integrated circuitry is a flip chip semiconductor die.

9. The apparatus of claim 7, wherein the memory integrated circuitry comprises:
DRAM memory integrated circuitry, or
NAND memory integrated circuitry.

10. The apparatus of claim 7, wherein the second substrate comprises:
a ceramic substrate, or
a silicon substrate, and
wherein the second quantity of two or more second conductive layers comprise:
two or more redistribution layers.

11. The apparatus of claim 7, wherein an area of the second substrate is less than or equal to an area of the semiconductor die.

12. A semiconductor package, comprising:
a first substrate, comprising;
a pad structure;
an external interconnect structure on the pad structure;
a second substrate, comprising:
a metallization layer;
a spacer that is between the first substrate and the second substrate; and
a semiconductor die on the first substrate,
wherein an electrical connection between the semiconductor die and the external interconnect structure includes the metallization layer and the pad structure.

13. The semiconductor package of claim 12, wherein the spacer is devoid of integrated circuitry.

14. The semiconductor package of claim 12, wherein the spacer includes integrated circuitry.

15. The semiconductor package of claim 12, wherein the metallization layer is a first metallization layer, and further comprising:
a wire bond that electrically connects the first metallization layer with a second metallization layer of the first substrate.

16. The semiconductor package of claim 15, further comprising:
a casing that is over the first substrate and that encapsulates the second substrate, the spacer, and the wire bond.

17. The semiconductor package of claim 12, wherein the electrical connection is part of a voltage supply circuit for powering a memory cell.

18. The semiconductor package of claim 12, wherein the electrical connection is part of a voltage supply circuit for powering input integrated circuitry or output integrated circuitry.

19. A method, comprising:
attaching a first semiconductor die to a first substrate;
attaching a second substrate to the first semiconductor die;
attaching a second semiconductor die to the first substrate; and
forming an electrical connection between a first metallization layer of the first substrate and a second metallization layer of the second substrate,
wherein forming the electrical connection electrically couples the first metallization layer to the second semiconductor die through the second metallization layer.

20. The method of claim 19, wherein attaching the second substrate to the first semiconductor die includes:
attaching the second substrate to the first semiconductor die using an adhesive film.

21. The method of the claim 19, wherein attaching the second semiconductor die to the first substrate electrically couples the second semiconductor die to the first metallization layer.

22. The method of claim 19, wherein forming the electrical connection includes:
forming a wire bond connection.

23. The method of claim 19, wherein the electrical connection is a first electrical connection and further comprising:
forming a second electrical connection between the second semiconductor die and a metallization layer of the first substrate.

24. The method of claim 23, wherein forming the second electrical connection includes:
forming a wire bond connection.

25. The method of claim 19, further comprising:
forming, over the first substrate, a casing that encapsulates the first semiconductor die, the second substrate, the second semiconductor die, and the electrical connection.
